(19) United States
(12) Patent Application Publication
(10) Pub. No.: US 2024/0249953 A1
(43) Pub. Date: Jul. 25, 2024

(54) DRY ETCH OF BORON-CONTAINING MATERIAL

(71) Applicant: Applied Materials, Inc., Santa Clara, CA (US)

(72) Inventors: Yeonju Kwak, Sunnyvale, CA (US); Jeong Hwan Kim, San Jose, CA (US); Qian Fu, Pleasanton, CA (US); Siyu Zhu, San Jose, CA (US); Hang Yu, San Jose, CA (US); Srinivas Guggilla, San Jose, CA (US)

(73) Assignee: Applied Materials, Inc., Santa Clara, CA (US)

(21) Appl. No.: 18/098,791

(22) Filed: Jan. 19, 2023

(51) Int. Cl. H01L 21/311; H01J 37/32

(52) U.S. Cl. CPC H01L 21/31122; H01J 37/32816; H01L 21/31144; H10B 69/00

(57) ABSTRACT

Exemplary methods of semiconductor processing may include providing a fluorine-containing precursor to a processing region of a semiconductor processing chamber. A substrate may be housed within the processing region. The substrate may include a boron-containing material overlying a carbon-containing material. The methods may include generating plasma effluents of the fluorine-containing precursor. The methods may include contacting the substrate with the plasma effluents of the fluorine-containing precursor. The methods may include removing the boron-containing material from the substrate.

### TECHNICAL FIELD

The present technology relates to semiconductor processes and materials. More specifically, the present technology relates to removing boron-containing material overlying other materials.

### BACKGROUND

Integrated circuits are made possible by processes which produce intricately patterned material layers on substrate surfaces. Producing patterned material on a substrate requires controlled methods of formation and removal of exposed material. Stacked memory, such as vertical or 3D NAND, may include the formation of a series of alternating layers of dielectric materials through which a number of memory holes or apertures may be etched. Material properties of the layers of materials, as well as process conditions and materials for etching, may affect the uniformity of the formed structures. Resistance to etchants may lead to inconsistent patterning, which may further affect the uniformity of the formed structures.

Thus, there is a need for improved systems and methods that can be used to produce high quality devices and structures. These and other needs are addressed by the present technology.

### SUMMARY

Exemplary methods of semiconductor processing may include providing a fluorine-containing precursor to a processing region of a semiconductor processing chamber. A substrate may be housed within the processing region. The substrate may include a boron-containing material overlying a carbon-containing material. The methods may include generating plasma effluents of the fluorine-containing precursor. The methods may include contacting the substrate with the plasma effluents of the fluorine-containing precursor. The methods may include removing the boron-containing material from the substrate.

In embodiments, the fluorine-containing precursor may be or include nitrogen trifluoride (NF₃). The boron-containing material may be characterized by a boron-content of greater than or about 20 at. %. The boron-containing material may further include nitrogen. The boron-containing material and the carbon-containing material may define at least one aperture extending through both the boron-containing material and the carbon-containing material. A temperature within the semiconductor processing chamber may be maintained at less than or about 100° C. A pressure within the semiconductor processing chamber may be maintained at less than or about 1 Torr. A plasma power may be maintained at greater than or about 1,000 W while generating plasma effluents of the fluorine-containing precursor. The boron-containing material may be removed from the substrate at a rate of greater than or about 5,000 Å/min. A selectivity of the removal of the boron-containing material relative to the carbon-containing material may be greater than or about 10:1.

Some embodiments of the present technology may encompass semiconductor processing methods. The methods may include providing a fluorine-containing precursor to a processing region of a semiconductor processing chamber. A substrate may be housed within the processing region. The substrate may include a boron-containing material overlying a carbon-containing hardmask material. The boron-containing material and the carbon-containing hardmask material may define at least one aperture extending through both the boron-containing material and the carbon-containing hardmask material. The methods may include generating plasma effluents of the fluorine-containing precursor. The methods may include contacting the substrate with the plasma effluents of the fluorine-containing precursor. The methods may include removing the boron-containing material from the substrate.

In embodiments, the fluorine-containing precursor may be or include nitrogen trifluoride (NF₃). A flow rate of the fluorine-containing precursor may be less than or about 1,000 sccm. The boron-containing material may be characterized by a thickness of greater than or about 250 nm. The fluorine-containing precursor may be provided to the processing region of the semiconductor processing chamber without a carrier gas. The methods may include, prior to providing the fluorine-containing precursor, etching the carbon-containing hardmask material to form the at least one aperture extending through the carbon-containing hardmask material. Removing the boron-containing material from the substrate may be performed in the same semiconductor processing chamber as etching the carbon-containing hardmask material.

Some embodiments of the present technology may encompass semiconductor processing methods. The methods may include providing fluorine-containing precursor to a processing region of a semiconductor processing chamber. The fluorine-containing precursor may be or include nitrogen trifluoride (NF₃). A substrate may be housed within the processing region. The substrate may include a boron-containing material overlying a carbon-containing material. The methods may include generating plasma effluents of the fluorine-containing precursor. A plasma power may be maintained at between about 500 W and about 3,000 W while generating plasma effluents of the fluorine-containing precursor. The methods may include contacting the substrate with the plasma effluents of the fluorine-containing precursor. The methods may include removing the boron-containing material from the substrate.

In embodiments, the boron-containing material may be removed from the substrate in less than or about 10 minutes. The carbon-containing material may define at least one aperture. Removing the boron-containing material from the substrate may maintain sidewalls and a bottom surface of the at least one aperture.

Such technology may provide numerous benefits over conventional systems and techniques. For example, the processes and structures may selectively remove boron-containing materials relative to carbon-containing materials and other materials during etching operations. Additionally, the operations of embodiments of the present technology may improve etch rates and may not result in and undercut profile on underlying materials, such as carbon-containing materials, and other underlying materials such as silicon oxide and/or silicon nitride. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic top plan view of an exemplary processing system according to some embodiments of the present technology.

FIG. 2 shows a schematic cross-sectional view of an exemplary processing system according to some embodiments of the present technology.

FIG. 3 shows selected operations in a formation method according to some embodiments of the present technology.

FIGS. 4A-4B illustrate schematic cross-sectional views of substrate materials on which selected operations are being performed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include superfluous or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As 3D NAND structures grow in the number of cells being formed, the aspect ratios of memory holes and other structures increase, sometimes dramatically. During 3D NAND processing, stacks of placeholder layers and dielectric materials may initially be formed, and within which the memory cells may be formed. These placeholder layers may have a variety of operations performed to place structures before fully removing the material and replacing it with metal. The layers are often formed overlying a conductor layer, such as polysilicon, for example. When the memory holes are formed, apertures may extend through all of the alternating layers of material before accessing the polysilicon or other material substrate. Subsequent processing may form a staircase structure for contacts, and may also exhume the placeholder materials laterally.

A reactive-ion etching (“RIE”) operation may be performed to produce the high aspect ratio memory holes. The RIE process often involves a combination chemical and physical removal of the alternating layers. As one non-limiting example, where the alternating layers may include silicon oxide and silicon nitride, the silicon oxide may be removed to a greater degree by physical bombardment of the layer during the RIE, and the silicon nitride may be removed to a greater degree by chemical reaction of the RIE precursors with the nitride materials.

Conventional technologies may struggle with uniformity and control during the memory hole formation due to material differences between the two layer types, as well as the RIE process and materials. Additionally, the memory hole may extend outward during etching, causing widening of a critical dimension within the stacked layer structure through which RIE may be performed to produce memory holes. Bowing may occur anywhere throughout a structure, and may be caused by a number of issues. For example, bowing may be caused by limited passivation on sidewalls, which may allow an amount of lateral etch to occur. Bowing may also occur due to changes with a hardmask material or other structural features. For example, if edges of a hardmask may become eroded during RIE processes, ions may be projected into the feature or memory hole at different directions or angles from normal to the substrate, which may produce additional lateral etching within some regions of the structure until the hardmask taper is removed or etched away. Additionally, memory holes may partially or completely clog due to re-deposition of etched material. Partial clogging may affect circularity of the memory holes. Partial or complete clogging may detrimentally effect electrical performance of final devices. In some technologies, the hardmask may not be perfectly uniform due to hardmask opening.

To compensate for these issues, conventional technologies have been limited in the number of stack layer pairs that can be etched at any time. As the number of layers increases, many conventional technologies will produce the structure in two discrete cycles. For example, conventional technologies may produce a first set of layers and etch through these layers. The memory holes may be plugged, and a second set of layers may be formed overlying the first set. The second set of layers may then be etched as well as the plug in the first set, with the intention of fully forming the structure. However, aligning the holes between the sets is rarely perfect, causing offsets that can affect production and cell formation. Additionally, by halting the formation between sets, material differences may develop due to different exposure and processing levels.

The present technology overcomes these issues by using a boron-containing material as a mask for opening the hardmask overlying the alternating layers. The boron-containing material may be prone to less clogging during the opening of the hardmask, which may form more uniform features or apertures in the hardmask. Additionally, intermittent flash operations during the etch may prevent clogging and therefore increase uniformity. The more uniform features or apertures may result in a more uniform etching of the alternating layers underlying the hardmask. However, unlike conventional technologies, conventional wet etches may not be able to remove the boron-containing material, or may remove the boron-containing material slowly or with poor selectivity. The present technology also overcomes these issues by removing the boron-containing material with a fluorine-containing precursor. The removal operations may remove the boron-containing material of different thickness across the substrate with minimal impact on the underlying materials, such as the hardmask.

Although the remaining disclosure will routinely identify specific materials and semiconductor structures utilizing the disclosed technology, it will be readily understood that the systems, methods, and materials are equally applicable to a number of other structures that may benefit from aspects of the present technology. Accordingly, the technology should not be considered to be so limited as for use with 3D NAND processes or materials alone. Moreover, although an exemplary chamber is described to provide foundation for the present technology, it is to be understood that the present technology can be applied to virtually any semiconductor processing chamber that may allow the operations described.

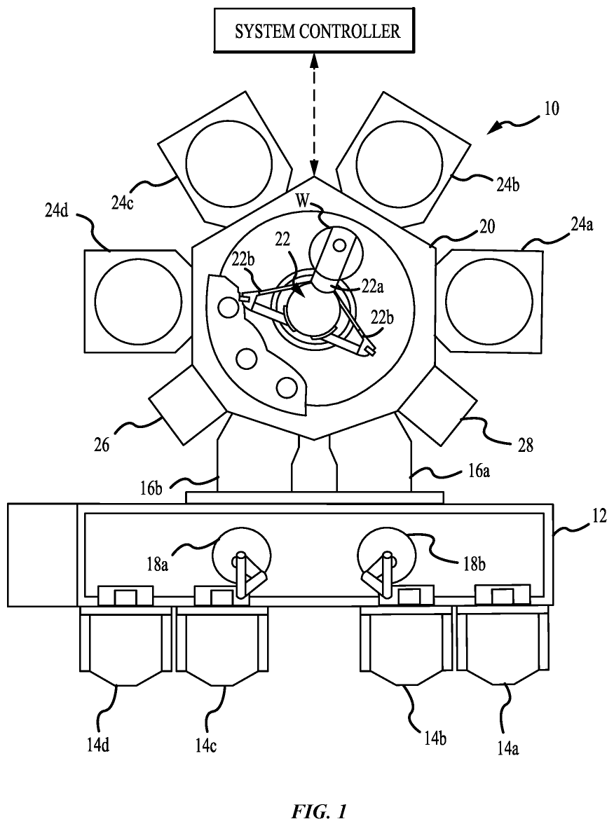

FIG. 1 shows a top plan view of one embodiment of a processing system 10 of deposition, etching, baking, and/or curing chambers according to embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 22b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

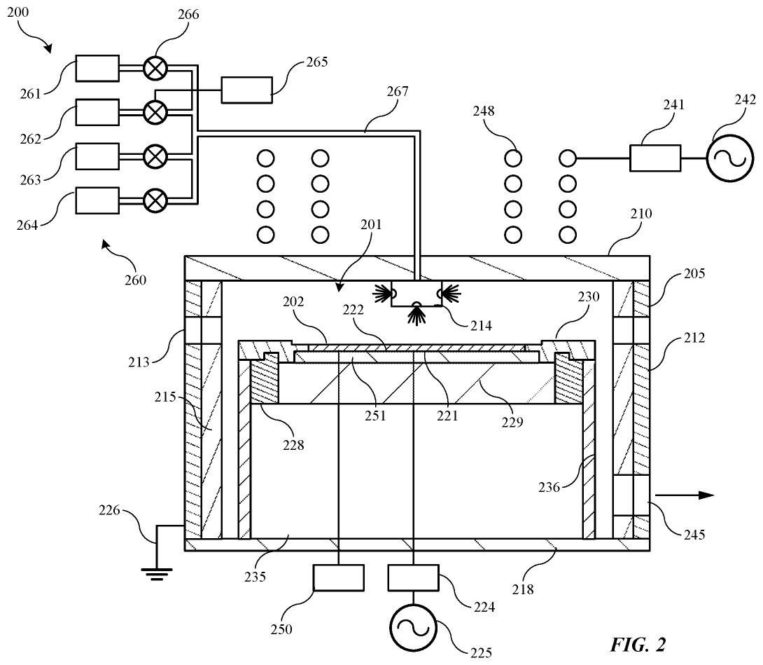

FIG. 2 illustrates a schematic cross-sectional view of an exemplary processing chamber 200 suitable for patterning a material layer disposed on a substrate 202 in the processing chamber 200. The exemplary processing chamber 200 is suitable for performing a patterning process, although it is to be understood that aspects of the present technology may be performed in any number of chambers, and substrate supports according to the present technology may be included in etching chambers, deposition chambers, treatment chambers, or any other processing chamber. The plasma processing chamber 200 may include a chamber body 205 defining a chamber volume 201 in which a substrate may be processed. The chamber body 205 may have sidewalls 212 and a bottom 218 which are coupled with ground 226. The sidewalls 212 may have a liner 215 to protect the sidewalls 212 and extend the time between maintenance cycles of the plasma processing chamber 200. The dimensions of the chamber body 205 and related components of the plasma processing chamber 200 are not limited and generally may be proportionally larger than the size of the substrate 202 to be processed therein. Examples of substrate sizes include 200 mm diameter, 250 mm diameter, 300 mm diameter and 450 mm diameter, among others, such as display or solar cell substrates as well.

The chamber body 205 may support a chamber lid assembly 210 to enclose the chamber volume 201. The chamber body 205 may be fabricated from aluminum or other suitable materials. A substrate access port 213 may be formed through the sidewall 212 of the chamber body 205, facilitating the transfer of the substrate 202 into and out of the plasma processing chamber 200. The access port 213 may be coupled with a transfer chamber and/or other chambers of a substrate processing system as previously described. A pumping port 245 may be formed through the sidewall 212 of the chamber body 205 and connected to the chamber volume 201. A pumping device may be coupled through the pumping port 245 to the chamber volume 201 to evacuate and control the pressure within the processing volume. The pumping device may include one or more pumps and throttle valves.

A gas panel 260 may be coupled by a gas line 267 with the chamber body 205 to supply process gases into the chamber volume 201. The gas panel 260 may include one or more process gas sources 261, 262, 263, 264 and may additionally include inert gases, non-reactive gases, and reactive gases, as may be utilized for any number of processes. Examples of process gases that may be provided by the gas panel 260 include, but are not limited to, hydrocarbon containing gas including methane, sulfur hexafluoride, silicon chloride, carbon tetrafluoride, hydrogen bromide, hydrocarbon containing gas, argon gas, chlorine, nitrogen, helium, or oxygen gas, as well as any number of additional materials. Additionally, process gasses may include nitrogen, chlorine, fluorine, oxygen, and hydrogen containing gases such as BCl₃, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional precursors.

Valves 266 may control the flow of the process gases from the sources 261, 262, 263, 264 from the gas panel 260 and may be managed by a controller 265. The flow of the gases supplied to the chamber body 205 from the gas panel 260 may include combinations of the gases form one or more sources. The lid assembly 210 may include a nozzle 214. The nozzle 214 may be one or more ports for introducing the process gases from the sources 261, 262, 264, 263 of the gas panel 260 into the chamber volume 201. After the process gases are introduced into the plasma processing chamber 200, the gases may be energized to form plasma. An antenna 248, such as one or more inductor coils, may be provided adjacent to the plasma processing chamber 200. An antenna power supply 242 may power the antenna 248 through a match circuit 241 to inductively couple energy, such as RF energy, to the process gas to maintain a plasma formed from the process gas in the chamber volume 201 of the plasma processing chamber 200. Alternatively, or in addition to the antenna power supply 242, process electrodes below the substrate 202 and/or above the substrate 202 may be used to capacitively couple RF power to the process gases to maintain the plasma within the chamber volume 201. The operation of the power supply 242 may be controlled by a controller, such as controller 265, that also controls the operation of other components in the plasma processing chamber 200.

A substrate support pedestal 235 may be disposed in the chamber volume 201 to support the substrate 202 during processing. The substrate support pedestal 235 may include an electrostatic chuck 222 for holding the substrate 202 during processing. The electrostatic chuck (“ESC”) 222 may use the electrostatic attraction to hold the substrate 202 to the substrate support pedestal 235. The ESC 222 may be powered by an RF power supply 225 integrated with a match circuit 224. The ESC 222 may include an electrode 221 embedded within a dielectric body. The electrode 221 may be coupled with the RF power supply 225 and may provide a bias which attracts plasma ions, formed by the process gases in the chamber volume 201, to the ESC 222 and substrate 202 seated on the pedestal. The RF power supply 225 may cycle on and off, or pulse, during processing of the substrate 202. The ESC 222 may have an isolator 228 for the purpose of making the sidewall of the ESC 222 less attractive to the plasma to prolong the maintenance life cycle of the ESC 222. Additionally, the substrate support pedestal 235 may have a cathode liner 236 to protect the sidewalls of the substrate support pedestal 235 from the plasma gases and to extend the time between maintenance of the plasma processing chamber 200.

Electrode 221 may be coupled with a power source 250. The power source 250 may provide a chucking voltage of about 200 volts to about 2000 volts to the electrode 221. The power source 250 may also include a system controller for controlling the operation of the electrode 221 by directing a DC current to the electrode 221 for chucking and de-chucking the substrate 202. The ESC 222 may include heaters disposed within the pedestal and connected to a power source for heating the substrate, while a cooling base 229 supporting the ESC 222 may include conduits for circulating a heat transfer fluid to maintain a temperature of the ESC 222 and substrate 202 disposed thereon. The ESC 222 may be configured to perform in the temperature range required by the thermal budget of the device being fabricated on the substrate 202. For example, the ESC 222 may be configured to maintain the substrate 202 at a temperature of about −150° C. or lower to about 500° C. or higher depending on the process being performed.

The cooling base 229 may be provided to assist in controlling the temperature of the substrate 202. To mitigate process drift and time, the temperature of the substrate 202 may be maintained substantially constant by the cooling base 229 throughout the time the substrate 202 is in the chamber. In some embodiments, the temperature of the substrate 202 may be maintained throughout subsequent processes at temperatures between about −150° C. and about 500° C., although any temperatures may be utilized. A cover ring 230 may be disposed on the ESC 222 and along the periphery of the substrate support pedestal 235. The cover ring 230 may be configured to confine etching gases to a desired portion of the exposed top surface of the substrate 202, while shielding the top surface of the substrate support pedestal 235 from the plasma environment inside the plasma processing chamber 200. Lift pins may be selectively translated through the substrate support pedestal 235 to lift the substrate 202 above the substrate support pedestal 235 to facilitate access to the substrate 202 by a transfer robot or other suitable transfer mechanism as previously described.

The controller 265 may be utilized to control the process sequence, regulating the gas flows from the gas panel 260 into the plasma processing chamber 200, and other process parameters. Software routines, when executed by the CPU, transform the CPU into a specific purpose computer such as a controller, which may control the plasma processing chamber 200 such that the processes are performed in accordance with the present disclosure. The software routines may also be stored and/or executed by a second controller that may be associated with the plasma processing chamber 200.

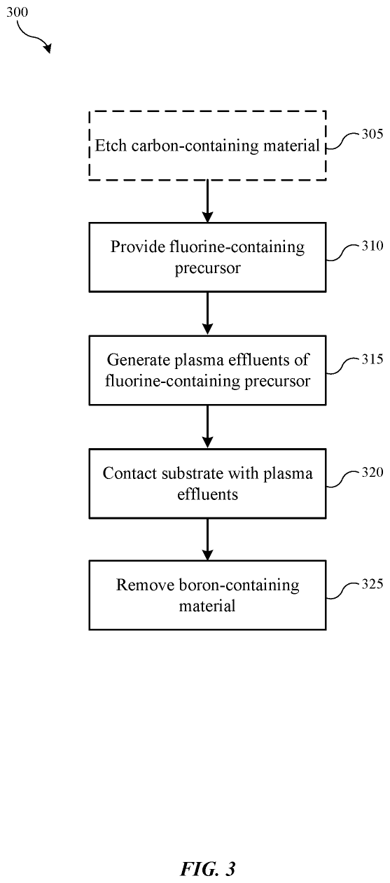

As noted above, the present technology may open a carbon-containing material, such as a carbon-containing hardmask material, using a boron-containing material as a mask overlying the carbon-containing material. Turning to FIG. 3 is shown exemplary operations in a method 300 of semiconductor processing according to embodiments of the present technology. Method 300 may include one or more operations prior to the initiation of the method, including front-end processing, deposition, etching, polishing, cleaning, or any other operations that may be performed prior to the described operations. For example, the method may begin after a number of layers of material overlying the boron-containing material have been patterned and/or removed, including the patterning of the boron-containing material. However, as explained above, it is to be understood that the figures illustrate just one exemplary process of carbon-containing material patterning according to embodiments of the present technology may be employed, and the description is not intended to limit the technology to this process alone. Some or all of the operations may be performed in chambers or system tools as previously described, or may be performed in different chambers on the same system tool, which may include the chamber in which the operations of method 300 may be performed.

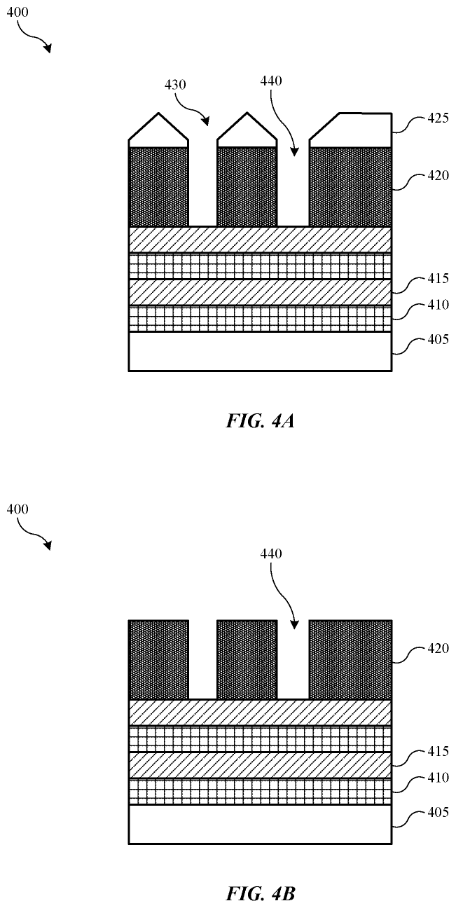

Method 300 may include a number of optional operations as illustrated, which may or may not be specifically associated with some embodiments of methods according to the present technology. For example, many of the operations are described in order to provide a broader scope of the structural formation, but are not critical to the technology, or may be performed by alternative methodology as will be discussed further below. Method 300 describes operations shown schematically in FIGS. 4A-4B, the illustrations of which will be described in conjunction with the operations of method 300. It is to be understood that FIGS. 4A-4B illustrate only partial schematic views, and a substrate may contain any number of structural sections having aspects as illustrated in the figures, as well as alternative structural aspects that may still benefit from operations of the present technology.

Method 300 may or may not involve optional operations to develop the semiconductor structure to a particular fabrication operation. It is to be understood that method 300 may be performed on any number of semiconductor structures, and FIGS. 4A-4B illustrate one exemplary structure within which an etching process may be performed. As illustrated in FIG. 4A a processed semiconductor structure 400 may include a substrate 405, which may have a plurality of stacked layers overlying the substrate, which may be a silicon-containing material, such as polysilicon, silicon germanium, or other substrate materials, and which may be conductors for contacts with subsequent metallization. As just one non-limiting example, the layers may include IPD layers including dielectric material 410, which may be silicon oxide, in alternating layers with placeholder material 415, which may be silicon nitride. Placeholder material 415 may be or include material that will be removed to produce individual memory cells in subsequent operations. Although illustrated with only four layers of material, exemplary structures may include any number of layers previously discussed, which can include dozens or hundreds of layers, and it is to be understood that the figures are only schematics to illustrate aspects of the present technology.

The exposed boron-containing material 425 may be characterized by a thickness of greater than or about 250 nm in embodiments, and may be characterized by a thickness of greater than or about 300 nm, greater than or about 350 nm, greater than or about 400 nm, greater than or about 450 nm, greater than or about 500 nm, or more. Conventional technologies may struggle with removing boron-containing material 425 characterized by a thickness of greater than or about 250 nm as the etch selectivity between the boron-containing material 425 and the mask material 420 may be poor. Additionally, conventional technologies may result in undercutting or damage to the mask material 420 during the removal of the boron-containing material 425 and/or to underlying materials, such as silicon oxide and/or silicon nitride. In embodiments, the boron-containing material may be characterized by a boron-content of greater than or about 20 at. %, such as greater than or about 22 at. %, greater than or about 24 at. %, greater than or about 26 at. %, greater than or about 28 at. %, greater than or about 30 at. %, greater than or about 32 at. %, greater than or about 34 at. %, greater than or about 36 at. %, greater than or about 38 at. %, greater than or about 40 at. %, or higher.

In embodiments, the boron-containing material 425 and mask material 420 may be characterized by cell areas, peri areas, and combinations thereof. Cell areas may include smaller widths of mask material 420 and, therefore, smaller widths of overlying boron-containing material 425. Peri areas may include wider widths of mask material 420 and, therefore, wider widths of overlying boron-containing material 425. The boron-containing material 425 overlying the mask material 420 in the peri areas may be thicker than the boron-containing material 425 overlying the mask material 420 in the cell areas. The present technology, as described below, may be able to remove boron-containing material 425 from cell areas and peri areas without damaging the underlying mask material 420 and without leaving boron-containing material 425 residue.

A mask material 420 may be formed overlying the IPD layers, and may be a carbon-containing material, such as a carbon-containing hardmask material of amorphous carbon, or any other carbon-containing material that may be formed over the underlying layers during subsequent cleaning and/or etching operation. A boron-containing material 425 may be disposed over the mask material 420. In embodiments, the boron-containing material 425 may also include nitrogen, and be a boron-and-nitrogen-containing material. The boron-containing material 425 may include a plurality of openings or apertures 430. The openings or apertures 430 may extend through an entire thickness of the boron-containing material 425, exposing the underlying mask material 420. The carbon-containing material of the mask material 420 may also include a plurality of openings or apertures 440. The openings or apertures 440 may extend through an entire thickness of the carbon-containing material of the mask material 420, exposing the underlying stacked layers of dielectric material 410 and placeholder material 415.

As shown in the figures, multiple materials may be present and exposed to etchant materials that may be used in the etching process. The method 300 may be performed to etch or remove the boron-containing material 425 to allow subsequent processing to proceed, while minimizing or eliminating etching or damage to the carbon-containing material of the mask material 420 and/or to underlying materials, such as silicon oxide and/or silicon nitride. By utilizing processing conditions and precursors according to embodiments of the present technology, etching of the mask material 420 may be limited or prevented during etching and removal of the boron-containing material 425.

As previously discussed, the boron-containing material 425 may be discontinuous, such that the material includes openings or apertures 430. The mask material 420 may be exposed within a recessed feature, such as openings or apertures 430, and may also include openings or apertures 440 that align with openings or apertures 430 of the boron-containing material 425. In embodiments, method 300 may include etching the mask material 420 to form the openings or apertures 440 at optional operation 305. The mask material 420 may be etched using any etching method, such as using an oxygen-containing precursor or plasma effluents thereof. The boron-containing material 425 may serve as a mask for opening the apertures 440 in the mask material 420. The etching at optional operation 305 may form features 440, which may be referred to as holes, in the mask material 420. An aspect ratio of the features or apertures 440 may be greater than or about 10:1, greater than or about 20:1, greater than or about 30:1, greater than or about 40:1, greater than or about 50:1, or greater.

Method 300 may include providing a fluorine-containing precursor to a processing region of a semiconductor processing chamber at operation 310. The processing region may house a substrate, such as processed semiconductor structure 400, which may have an exposed boron-containing material 425, such as boron-and-nitrogen-containing material, and an exposed carbon-containing material, such as mask material 420, which may be a carbon-containing hardmask and/or to underlying materials, such as silicon oxide and/or silicon nitride. For processing to continue, such as to etch material underlying the mask material 420, the boron-containing material 425 may need to be removed. If present on the substrate 405, the boron-containing material 425 may have a negative impact on subsequent operations or may defects more likely. The fluorine-containing precursor may be provided to the processing region to selectively remove the boron-containing material 425 relative to the underlying mask material 420.

The fluorine-containing precursor used in the method 300 may include any fluorine-containing precursor. An exemplary fluorine-containing precursor may be nitrogen trifluoride (NF₃), which may be flowed into the processing region, without passing through any plasma along the way. Other sources of fluorine may be used in conjunction with or as replacements for the nitrogen trifluoride. In general, a fluorine-containing precursor may be flowed into the processing region and the fluorine-containing precursor may include at least one precursor selected from the group of atomic fluorine, diatomic fluorine, nitrogen trifluoride, carbon tetrafluoride (CF₄), hydrogen fluoride (HF), sulfur hexafluoride (SF₆), xenon difluoride (XeF₂), and various other fluorine-containing precursors used or useful in semiconductor processing. The precursors may also include any number of carrier gases, which may include nitrogen, helium, argon, or other noble, inert, or useful precursors. The carrier gases may be used to dilute the fluorine-containing precursor, which may reduce etching rates to allow adequate control of the etch. However, it is contemplated that the fluorine-containing precursor may be provided without any other gases.

The flow rates of one or more of the fluorine-containing precursor may also be adjusted, along with any other processing conditions. For example, a flow rate of the fluorine-containing precursor may be reduced, maintained, or increased during method 300. During any of the operations of method 300, the flow rate of the fluorine-containing precursor may be between about 2 sccm and about 1,000 sccm. Additionally, the flow rate of the fluorine-containing precursor may be less than or about 900 sccm, less than or about 800 sccm, less than or about 700 sccm, less than or about 600 sccm, less than or about 500 sccm, less than or about 400 sccm, less than or about 300 sccm, less than or about 250 sccm, less than or about 200 sccm, less than or about 150 sccm, less than or about 100 sccm, or more. The flow rate may also be between any of these stated flow rates, or within smaller ranges encompassed by any of these numbers.

Method 300 may include forming plasma within the processing region of the semiconductor processing chamber at operation 315. The plasma may generate plasma effluents of the fluorine-containing precursor. Operations 310 and 315 may occur sequentially or may be performed substantially simultaneously in some embodiments. Additionally, the plasma may be formed initially from the fluorine-containing precursor or, if present, from one or more inert precursors prior to addition of the fluorine-containing in different embodiments.

The local plasma formed of the fluorine-containing precursor may provide directional flow of plasma effluents to the boron-containing material 425 to provide efficient removal of the boron-containing material 425. The plasma may be a low-level plasma to limit the amount of bombardment, sputtering, and surface modification. In embodiments, the plasma power may be less than or about 5,000 W, less than or about 4,500 W, less than or about 4,000 W, less than or about 3,500 W, less than or about 3,000 W, less than or about 2,500 W, less than or about 2,000 W, less than or about 1,500 W, less than or about 1,000 W, or less. By utilizing a plasma power that is, for example, about 4,000 W or less, the plasma effluents may be better controlled for less profiling and/or damage to exposed surfaces, such as the mask material 420. However, at too low of a plasma power, such as less than or about 500 W, an etch rate of the boron-containing material 425 may be sacrificed, resulting is slower throughput and increased queue times. In embodiments, the plasma power may be greater than or about 500 W, greater than or about 600 W, greater than or about 700 W, greater than or about 800 W, greater than or about 900 W, greater than or about 1,000 W, greater than or about 1,250 W, greater than or about 1,500 W, greater than or about 1,750 W, greater than or about 2,000 W, or higher. Accordingly, the plasma power may be maintained at between about 500 W and about 3,000 W, or at any range between.

Semiconductor structure 400 may be contacted with the plasma effluents at operation 320, which may perform an etch or removal of the boron-containing material 425 at operation 325. As illustrated in FIG. 4B, plasma effluents may contact the semiconductor structure 400, and may contact all exposed surfaces, including surfaces to be etched, such as the boron-containing material 425, as well as surfaces to be maintained, such as mask material 420, placeholder material 415, and/or dielectric material 410, which may include sidewalls and/or bottom surfaces of the apertures 440 in the materials. During operation 325, sidewalls and/or bottom surfaces of the apertures 440 in the mask material may be maintained with minimal or zero modification or damage.

Embodiments of the present technology may remove the boron-containing material 425 relative to the mask material 420 or any of the other materials at a rate of at least about 10:1, and may etch the boron-containing material 425 relative to the mask material 420 or any of the other materials at a selectivity greater than or about 15:1, greater than or about 20:1, greater than or about 25:1, greater than or about 30:1, greater than or about 50:1, greater than or about 100:1, greater than or about 150:1, greater than or about 200:1, greater than or about 250:1, greater than or about 300:1, greater than or about 350:1, greater than or about 400:1, greater than or about 450:1, greater than or about 500:1, or more. For example, etching performed according to some embodiments of the present technology may etch the boron-containing material 425 while substantially or essentially maintaining the mask material 420 or other materials.

Embodiments of the present technology may quickly and efficiently remove the boron-containing material 425. Many conventional technologies, such as wet etch processes, may require significant operation times to completely remove boron-containing materials. The precursors and/or operation conditions of the present embodiments may provide increased removal rates. In embodiments, the boron-containing material 425 may be removed from the substrate 405 at a rate of greater than or about 5,000 Å/min, and may be removed at a rate of greater than or about 5,500 Å/min, greater than or about 6,000 Å/min, greater than or about 6,500 Å/min, greater than or about 7,000 Å/min, greater than or about 7,500 Å/min, greater than or about 8,000 Å/min, greater than or about 8,500 Å/min, greater than or about 9,000 Å/min, or higher.

Accordingly, the etching operations may be performed in a single cycle in some embodiments, although multiple cycles of etching may be performed. Additionally, the process may fully remove the boron-containing material 425 in a time period less than or about 10 minutes, less than or about 9 minutes, less than or about 8 minutes, less than or about 7 minutes, less than or about 6 minutes, less than or about 5 minutes, less than or about 4 minutes, less than or about 3 minutes, less than or about 2 minutes, less than or about 1 minute, or less.

Process conditions may impact the operations performed in method 300. Each of the operations of method 300 may be performed during a constant temperature in embodiments, while in some embodiments the temperature may be adjusted during different operations. For example, the substrate, pedestal, or chamber temperature during processing may be maintained at a temperature less than or about 100° C., less than or about 90° C., less than or about 80° C., less than or about 70° C., less than or about 60° C., less than or about 50° C., and in some embodiments the temperature may be maintained less than or about 40° C., less than or about 30° C., less than or about 20° C., less than or about 10° C., less than or about 0° C., less than or about −10° C., less than or about −20° C., less than or about −30° C., or less. Maintaining the substrate, pedestal, or chamber temperatures at lower relative temperatures may minimize damage to the semiconductor structure 400, such as to sidewalls and/or bottom surfaces of the apertures 440 in the mask material 420 during removal of the boron-containing material 425. However, as temperatures decrease, etch rate may decrease and overall throughput may increase. Accordingly, the substrate, pedestal, or chamber temperature during processing may be maintained at a temperature between about −30° C. and about 100° C.

The pressure within the processing chamber may be controlled during method 300. For example, the pressure within the processing chamber may be maintained below or about 1 Torr. Additionally, in embodiments, the pressure within the processing chamber may be maintained below or about 750 mTorr, below or about 500 mTorr, below or about 250 mTorr, below or about 100 mTorr, below or about 80 mTorr, below or about 60 mTorr, below or about 50 mTorr, below or about 40 mTorr, below or about 30 mTorr, below or about 20 mTorr, or lower, although the pressure may also be included in ranges between any two of these stated numbers or within any smaller range encompassed by any of the stated ranges. Pressure may affect uniformity of the removal. For example, as pressure increases, a less uniform removal of boron-containing material 425 occurs. Additionally, as pressure decreases, such as below 1 mTorr, plasma density may also decrease. At lower plasma densities, the removal rate may decrease and may decrease throughput time.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the material” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a fluorine-containing precursor to a processing region of a semiconductor processing chamber, wherein a substrate is housed within the processing region, and wherein the substrate comprises a boron-containing material overlying a carbon-containing material;
generating plasma effluents of the fluorine-containing precursor;
contacting the substrate with the plasma effluents of the fluorine-containing precursor; and
removing the boron-containing material from the substrate.

2. The semiconductor processing method of claim 1, wherein the fluorine-containing precursor comprises nitrogen trifluoride (NF₃).

3. The semiconductor processing method of claim 1, wherein the boron-containing material is characterized by a boron-content of greater than or about 20 at. %.

4. The semiconductor processing method of claim 1, wherein the boron-containing material further comprises nitrogen.

5. The semiconductor processing method of claim 1, wherein the boron-containing material and the carbon-containing material define at least one aperture extending through both the boron-containing material and the carbon-containing material.

6. The semiconductor processing method of claim 1, wherein a temperature within the semiconductor processing chamber is maintained at less than or about 100° C.

7. The semiconductor processing method of claim 1, wherein a pressure within the semiconductor processing chamber is maintained at less than or about 1 Torr.

8. The semiconductor processing method of claim 1, wherein a plasma power is maintained at greater than or about 1,000 W while generating plasma effluents of the fluorine-containing precursor.

9. The semiconductor processing method of claim 1, wherein the boron-containing material is removed from the substrate at a rate of greater than or about 5,000 Å/min.

10. The semiconductor processing method of claim 1, wherein a selectivity of the removal of the boron-containing material relative to the carbon-containing material is greater than or about 10:1.

11. A semiconductor processing method comprising:
providing a fluorine-containing precursor to a processing region of a semiconductor processing chamber, wherein a substrate is housed within the processing region, wherein the substrate comprises a boron-containing material overlying a carbon-containing hardmask material, and wherein the boron-containing material and the carbon-containing hardmask material define at least one aperture extending through both the boron-containing material and the carbon-containing hardmask material;
generating plasma effluents of the fluorine-containing precursor;
contacting the substrate with the plasma effluents of the fluorine-containing precursor; and
removing the boron-containing material from the substrate.

12. The semiconductor processing method of claim 11, wherein the fluorine-containing precursor comprises nitrogen trifluoride (NF₃).

13. The semiconductor processing method of claim 11, wherein a flow rate of the fluorine-containing precursor is less than or about 1,000 sccm.

14. The semiconductor processing method of claim 11, wherein the boron-containing material is characterized by a thickness of greater than or about 250 nm.

15. The semiconductor processing method of claim 11, wherein the fluorine-containing precursor is provided to the processing region of the semiconductor processing chamber without a carrier gas.

16. The semiconductor processing method of claim 11, further comprising:
prior to providing the fluorine-containing precursor, etching the carbon-containing hardmask material to form the at least one aperture extending through the carbon-containing hardmask material.

17. The semiconductor processing method of claim 16, wherein removing the boron-containing material from the substrate is performed in the same semiconductor processing chamber as etching the carbon-containing hardmask material.

18. A semiconductor processing method comprising:
providing fluorine-containing precursor to a processing region of a semiconductor processing chamber, wherein the fluorine-containing precursor comprises nitrogen trifluoride (NF₃), wherein a substrate is housed within the processing region, and wherein the substrate comprises a boron-containing material overlying a carbon-containing material;
generating plasma effluents of the fluorine-containing precursor, wherein a plasma power is maintained at between about 500 W and about 3,000 W while generating plasma effluents of the fluorine-containing precursor;
contacting the substrate with the plasma effluents of the fluorine-containing precursor; and
removing the boron-containing material from the substrate.

19. The semiconductor processing method of claim 18, wherein the boron-containing material is removed from the substrate in less than or about 10 minutes.

20. The semiconductor processing method of claim 18, wherein:
the carbon-containing material defines at least one aperture; and
removing the boron-containing material from the substrate maintains sidewalls and a bottom surface of the at least one aperture.
